(19) United States
(12) Patent Application Publication
(10) Pub. No.: US 2016/0380105 A1
(43) Pub. Date: Dec. 29, 2016

(54) OXIDE THIN FILM TRANSISTOR AND METHOD FOR MANUFACTURING THE SAME, ARRAY SUBSTRATE AND METHOD FOR MANUFACTURING THE SAME, AND DISPLAY DEVICE

(71) Applicant: BOE TECHNOLOGY GROUP CO., LTD., Beijing (CN)

(72) Inventor: Ke WANG, Beijing (CN)

(21) Appl. No.: 15/131,644

(22) Filed: Apr. 18, 2016

(30) Foreign Application Priority Data
Jun. 23, 2015 (CN) 201510350266.3

(51) Int. Cl. H01L 29/786; H01L 27/12; H01L 29/08; H01L 29/66; H01L 23/31

(52) U.S. Cl. CPC H01L 29/7869; H01L 29/66969; H01L 23/3171; H01L 29/0843; H01L 27/1225

(57) ABSTRACT

The present invention provides an oxide thin film transistor and a method for manufacturing the same, an array substrate and a method for manufacturing the same, and a display device, belonging to the field of display technology. The method for manufacturing an oxide thin film transistor of the present invention comprises: forming a pattern comprising an active layer, a source and a drain of the oxide thin film transistor above a substrate by a patterning process; and annealing the substrate subjected to the above step. The oxide thin film transistor manufactured by the manufacturing method of the present invention has stable performance.

### FIELD OF THE INVENTION

The present invention belongs to the field of display technology, and particularly relates to an oxide thin film transistor and a method for manufacturing the same, an array substrate and a method for manufacturing the same, and a display device.

### BACKGROUND OF THE INVENTION

At present, the oxide thin film transistor (TFT) technology has become the mainstream technology of flat panel display products of large size, high quality and low power consumption, and has been produced in mass or actively developed by various panel manufacturers. In the prior art, the manufacturing process of oxide thin film transistor arrays usually includes the following steps.

A buffer layer of a silicon dioxide (SiO₂) and silicon nitride (SiNx) thin film is formed on the entire substrate by plasma enhanced chemical vapor deposition (PECVD). Subsequently, a pattern including an active layer is formed on the buffer layer by a patterning process.

An etching stop layer (ESL) is formed on the substrate on which the active layer is formed, and a via hole through which a source and a drain is connected to the active layer is formed;

One or more low-resistance metal thin films are deposited by magnetron sputtering, a source and a drain are formed by exposure and etching processes.

A SiO₂ thin film or a SiO₂ and SiNx thin film is deposited by PECVD, and a gate insulating layer is formed on the substrate on which the active layer is formed. One or more low-resistance metal thin films are formed on the gate insulating layer by a physical vapor deposition method such as magnetron sputtering, and a gate is formed by a photolithographic process.

On the substrate on which the gate is formed, a SiO₂ and SiNx thin film is deposited by PECVD, and a passivation layer (PVX) and a via hole through which the drain is connected to a pixel electrode are formed by exposure and etching processes.

On the substrate subjected to the above step, a transparent conductive thin film is deposited by magnetron sputtering, and a pixel electrode in a pixel region is formed by a photolithographic process.

On the substrate subjected to the above step, a planarization layer is formed.

On the substrate subjected to the above step, a pattern including a common electrode is formed by a patterning process.

### SUMMARY OF THE INVENTION

### Problems to be Solved in the Present Invention

It has been found by the inventor that the prior art described above at least has the following problems: the cost is high since seven to nine times of exposure are required; furthermore, Cgs (parasitic capacitance between the gate, the source and the drain) occurs in both ESL and BCE (back-channel etching) structures, thereby resulting in large panel load (signal delay of the display panel), increasing the power consumption and bringing some restrictions to the MUX design and application of high-resolution products. In addition, in the existing oxide thin film transistors, the source and the drain are in insufficient Ohmic contact with the active layer, respectively. Accordingly, the switching characteristics of the device are to be improved.

The technical problems to be solved in the present invention includes, in view of the above problems of the existing methods for manufacturing a thin film transistor and an array substrate, providing an oxide thin film transistor and a method for manufacturing the same, an array substrate and a method for manufacturing the same, and a display device, which are simple in process and good in performance.

### Solutions to the Problems

According to one embodiment of the present invention, a method for manufacturing an oxide thin film transistor is provided, including:

a step of forming a pattern including an active layer, a source and a drain above a substrate by a patterning process; and

a step of annealing the substrate subjected to the above step.

Preferably, the step of forming a pattern including an active layer, a source and a drain by a patterning process includes:

successively depositing an oxide semiconductor thin film and a source-drain metal thin film, and forming a pattern including an active layer, a source and a drain by a single patterning process.

Further preferably, annealing of the substrate, above which the active layer, the source and the drain are formed, is performed for 30-60 min at a temperature of 230-320° C.

Preferably, the step of forming a pattern including an active layer, a source and a drain by a patterning process includes:

a step of depositing an oxide semiconductor thin film and forming a pattern including an active layer by a patterning process; and

a step of depositing a source-drain metal thin film and forming a pattern including a source and a drain by a patterning process.

Further preferably, before the step of forming a pattern including a source and a drain by a patterning process, the method further includes: a step of annealing the substrate above which the active layer is formed.

Further preferably, annealing the substrate, above which the active layer is formed, is performed for 30-60 min at a temperature of 230-320° C.

Further preferably, in the step of annealing the substrate above which the source and the drain of the thin film transistor are formed, the annealing is performed for 5-10 min at a temperature of 230-320° C.

Preferably, the source and the drain are made of any one of molybdenum, molybdenum-niobium alloy, aluminum, aluminum-neodymium alloy, titanium or copper.

According to another embodiment of the present invention, an oxide thin film transistor is provided, being manufactured by the manufacturing method as described above.

According to another embodiment of the present invention, a method for manufacturing an array substrate is provided, including the method for manufacturing an oxide thin film transistor as described above.

Preferably, the method for manufacturing an array substrate further includes:

after the step of annealing a substrate above which a source and a drain are formed, depositing a passivation layer and forming a via hole through which a pixel electrode is connected to the drain by etching; and

forming a pattern including a pixel electrode by a patterning process, the pixel electrode being connected to the drain through the via hole.

Further preferably, the passivation layer is a single-layer structure of silicon dioxide, or a dual-layer structure of silicon dioxide and silicon nitride, or a tri-layer structure of silicon dioxide, silicon nitride and silicon oxynitride.

According to another embodiment of the present invention, an array substrate is provided, being manufactured by the manufacturing method as described above.

According to another embodiment of the present invention, a display device is provided, including the array substrate as described above.

The present invention has the following beneficial effects.

According to the method for manufacturing an oxide thin film transistor of the present invention, after forming the active layer, and the source and the drain, annealing is performed. At that time, at positions where the source and the drain come into contact with the active layer, metal atoms in the metal material forming the source and the drain will be diffused toward the active layer to undergo chemical reaction with oxygen atoms in the oxide semiconductor material forming the active layer so as to produce oxides. As a result, the active layer material at those positions undergoes oxygen loss. That is, the oxygen vacancies are increased, and the free electrons are increased accordingly. Consequently, the semiconductor material at those positions has a metalized (semiconductor) tendency. Hence, the Ohmic contact between the source and the active layer and between the drain and the active layer, respectively, can be increased, so that the performance of the oxide thin film transistors becomes better. Specifically, in the case of good Ohmic contact, the ON current (i.e., Ion) of the TFTs is high and may reach 10⁻⁴ A, while in the case of poor Ohmic contact, the ON current will become very low and may reach 10⁻⁷ to 10⁻⁶ A.

### BRIEF DESCRIPTION OF THE DRAWINGS

FIG. 1 is a schematic diagram of a method for manufacturing an oxide thin film transistor of Embodiment 1 of the present invention;

FIG. 2 is a schematic diagram of a method for manufacturing an oxide thin film transistor of Embodiment 2 of the present invention;

FIG. 3 is a schematic diagram of a method for manufacturing an oxide thin film transistor of Embodiment 3 of the present invention; and

FIG. 4 is a schematic diagram of a method for manufacturing an array substrate of Embodiment 4 of the present invention.

### REFERENCE SIGNS

1: active layer;

21: source;

22: drain;

3: gate insulating layer;

4: gate;

5: passivation layer;

6: pixel electrode;

7: planarization layer;

8: common electrode;

9: substrate;

10: oxide semiconductor thin film;

20: source-drain metal thin film;

11: photoresist.

### DETAILED DESCRIPTION OF THE EMBODIMENTS

To make those skilled in the art better understand the technical solutions of the present invention, the present invention will be further described in detail below in conjunction with the accompanying drawings and specific embodiments.

### Embodiment 1

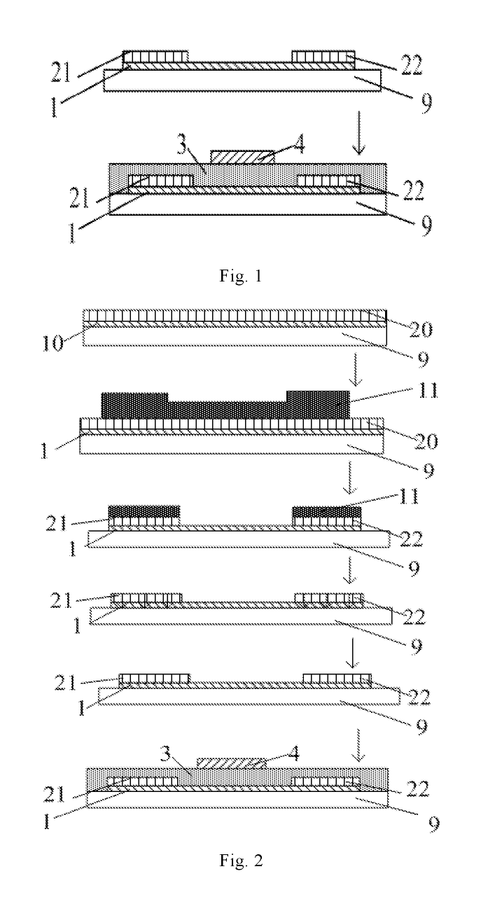

FIG. 1 is a schematic diagram of a method for manufacturing an oxide thin film transistor of Embodiment 1 of the present invention. As shown in FIG. 1, this embodiment provides a method for manufacturing an oxide thin film transistor, including: forming a pattern including an active layer 1, a source 21 and a drain 22 above a substrate 9 by a patterning process; and a step of annealing the substrate 9 subjected to the above step. Thereafter, the method further includes a step of forming a gate insulating layer 3 and a gate 4 of the oxide thin film transistor.

In this embodiment, annealing is performed after forming the active layer 1, and the source 21 and the drain 22 of the oxide thin film transistor. As compared with the case in which no annealing is performed, when annealing is performed, at positions where the source 21 and the drain 22 come into contact with the active layer 1 respectively, the diffusion of metal atoms in the metal material forming the source 21 and the drain 22 toward the active layer 1 can be facilitated, the metal atoms entering the active layer 1 by diffusion undergo chemical reaction with oxygen atoms in the oxide semiconductor material forming the active layer 1. As a result, the active layer 1 material at those positions undergoes oxygen loss. That is, the oxygen vacancies are increased, and the free electrons are increased accordingly. Consequently, the semiconductor material at those positions has a metalized (semiconductor) tendency. Hence, the Ohmic contact between the source 21 and the active layer 1 and between the drain 22 and the active layer 1, respectively, is further increased, so that the performance of the oxide thin film transistors becomes better.

It may be understood that, when forming a pattern including an active layer 1, a source 21 and a drain 22, above the substrate 9, the metal of the source 21 and the drain 22 will be naturally diffused toward the active layer 1. However, such diffusion is quite slow, and as a result, the source 21 and the drain 22 are in insufficient Ohmic contact with the active layer 1, respectively. In contrast, according to this embodiment, since annealing is performed after forming a pattern including an active layer 1, a source 21 and a drain 22 by a patterning process, such diffusion may be accelerated greatly.

It is to be noted that, in the present invention, “Ohmic contact” refers to contact between the metal and the semiconductor. Since the resistance of the contact surface is far less than the resistance of the semiconductor itself, during the operation of the assembly, most voltage drops occur in the active region instead of the contact surface. Ohmic contact means that no obvious additional impedance is produced, and no obvious change in concentration of equilibrium carriers inside the semiconductor is caused.

Additionally, according to this embodiment, conditions for annealing are not specifically limited, as long as it can facilitate the diffusion of metal atoms in the metal material forming the source 21 and the drain 22 towards the active layer 1.

It is to be noted that, in this embodiment and in the following embodiments, the patterning process may include only the photolithographic process, or, may include the photolithographic process and the etching step and also may include printing, inkjet and other processes for forming a predetermined pattern. The photolithographic process is a process of forming a pattern by a photoresist, a mask plate, an exposing machine or the like, including film forming, exposing, developing and other processes. A corresponding patterning process may be selected according to the structure formed in this embodiment.

### Embodiment 2

FIG. 2 is a schematic diagram of a method for manufacturing an oxide thin film transistor of Embodiment 2 of the present invention. As shown in FIG. 2, this embodiment provides a method for manufacturing an oxide thin film transistor. This embodiment is a preferred implementation of Embodiment 1, and specifically includes the following steps.

Step 1: A pattern including an active layer 1, a source 21 and a drain 22 of an oxide thin film transistor is formed on a substrate 9 by a patterning process.

In this step, an oxide semiconductor thin film 10 is deposited on the substrate 9 by sputtering, thermal evaporation, plasma enhanced chemical vapor deposition (PECVD), low pressure chemical vapor deposition (LPCVD), atmospheric pressure chemical vapor deposition (APCVD) or electron cyclotron resonance chemical vapor deposition (ECR-CVD), then a source-drain metal thin film 20 is deposited by PECVD, LPCVD, APCVD or ECR-CVD or sputtering, and thereafter a photoresist 11 is applied onto the source-drain metal thin film 20. It is to be noted that the substrate 9 is made of transparent material, such as glass, and is cleared in advance.

Next, a pattern including a source 21, a drain 22 and an active layer 1 is formed simultaneously by a single patterning process by using a half tone mask (HTM) or a gray tone mask (GTM). In the present invention, a “single patterning process” is a process in which a pattern including a source 21, a drain 22 and an active layer 1 could be formed by one procedure including film forming, exposing, developing, wet etching or dry etching. In the present invention, since a pattern including a source 21, a drain 22 and an active layer 1 is formed simultaneously by this single patterning process, compared with the prior art, the number of times of exposure can be reduced, and the cost is thus reduced.

The oxide semiconductor thin film 10 is made of any one of ITO (indium tin oxide), IZO (indium zinc oxide), IGZO (indium gallium zinc oxide) or InGaSnO (indium gallium tin oxide). The oxide semiconductor thin film 10 has a thickness of 40-50 nm, and during the deposition, the content of oxygen in the deposition atmosphere is 15%-30%.

The source-drain metal thin film 20 is made of any one of molybdenum, molybdenum-niobium alloy, aluminum, aluminum-neodymium alloy, titanium or copper. The source-drain metal thin film 20 has a thickness of 20-30 nm. It is to be noted here that the source-drain metal thin film 20 may be a single-layer structure of metal, may also be a dual-layer structure of buffer metal/metal, and may also be a tri-layer structure of buffer metal/metal/buffer metal.

Step 2: Annealing is performed on the substrate subjected to the above step. The annealing temperature is not specifically limited, and may be selected according to the material forming the substrate 9, the active layer 1, the source 21 and the drain 22. However, the annealing temperature is preferably 30-320° C. When the annealing temperature is too low, it is unable to effectively enable the diffusion of metal atoms in the source-drain metal thin film 20 towards the active layer, while when the annealing temperature is too high, it is possible to damage (for example, deform, degrade or the like) the material forming the substrate 9 and the active layer 1 and increase the annealing cost. When the annealing temperature is within the above range, it can effectively enable the diffusion of metal atoms in the source-drain metal thin film 20 towards the active layer, without damaging the material forming the substrate 9 and the active layer 1.

The annealing duration is not specifically limited, and may be set according to actual needs. However, the annealing duration is preferably 30-60 min. When the annealing duration is too short, it is unable to effectively enable the diffusion of metal atoms in the source-drain metal thin film 20 towards the active layer, while when the annealing duration is too long, since the metal diffusion achieves a balance, it may prolong the production cycle and cause waste and thus increase the cost.

By Step 2, at positions where the source 21 and the drain 22 come into contact with the active layer 1 respectively, the diffusion of metal atoms in the metal material forming the source 21 and the drain 22 toward the active layer 1 can be facilitated, the metal atoms entering the active layer 1 by diffusion undergo chemical reaction with oxygen atoms in the oxide semiconductor material forming the active layer 1. As a result, the active layer 1 material at those positions undergoes oxygen loss. That is, the oxygen vacancies are increased, and the free electrons are increased accordingly. Consequently, the semiconductor material at those positions has a metalized (semiconductor) tendency. Hence, the Ohmic contact between the source 21 and the active layer 1 and between the drain 22 and the active layer 1, respectively, is further increased. In addition, the stability of the channel region of the active layer 1 may also be enhanced. Herein, annealing in the presence of air or O₂ may supplement O₂ to the active layer 1. The content of oxygen in the active layer is controlled so that the characteristics of the semiconductor in the active layer become more stable, and thus the performance of the oxide thin film transistors becomes better.

Step 3: A gate insulating layer 3 and a gate metal thin film are formed on the substrate 9 subjected to the above step, and a pattern including a gate 4 is formed by a patterning process.

In this step, first, a gate insulating layer is formed on the substrate 9 subjected to Step 2 by PECVD, LPCVD, APCVD or ECR-CVD or sputtering; then, a gate metal thin film is formed by sputtering, thermal evaporation, PECVD, LPCVD, APCVD or ECR-CVD; and finally, a pattern including a gate 4 is formed by a patterning process.

The gate insulating layer 3 may be made of silicon oxide (SiOx), silicon nitride (SiNx), hafnium oxide (HfOx), silicon oxynitride (SiON), aluminum oxide (AlOx) or the like, or may be made of a multi-layer film of two or three thereof. The gate insulating layer 3 has a thickness of 200-300 nm. The gate metal thin film is made of one of molybdenum (Mo), molybdenum-niobium alloy (MoNb), aluminum (Al), aluminum-neodymium alloy (AlNd), titanium (Ti) or copper (Cu), or made of a single-layer or multi-layer composite laminated layer of more thereof, preferably, the gate metal thin film is made of Mo, Al, or a single-layer or multi-layer composite film of alloy containing Mo, Al. The gate insulating layer has a thickness of 200-300 nm.

So far, an oxide thin film transistor has been manufactured.

Correspondingly, in this embodiment, an oxide thin film transistor is further provided, which is manufactured according to the method as described above, so the performance of this oxide thin film transistor is more stable. Furthermore, in the method for manufacturing an oxide thin film transistor in this embodiment, since the active layer, the source and the drain are formed by a single patterning process, the patterning process is simple.

### Embodiment 3

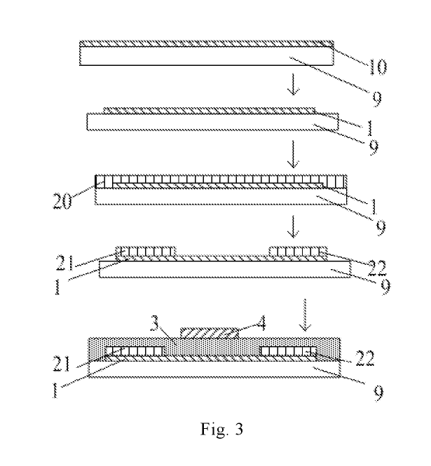

FIG. 3 is a schematic diagram of a method for manufacturing an oxide thin film transistor of Embodiment 3 of the present invention. As shown in FIG. 3, this embodiment also provides a method for manufacturing an oxide thin film transistor. The manufacturing method in this embodiment is similar to the method in Embodiment 2. The difference lies in the step of forming the active layer 1, the source 21 and the drain 22 of an oxide thin film transistor. In this embodiment, the active layer 1, the source 21 and the drain 22 of an oxide thin film transistor are formed by twice patterning processes. The method specifically includes:

forming a pattern including an active layer 1 of an oxide thin film transistor on a substrate 9 by a patterning process.

In this step, the substrate 9 is made of transparent material, for example, glass, and is cleared in advance. Specifically, an oxide semiconductor thin film 10 is deposited by sputtering, thermal evaporation, PECVD, LPCVD, APCVD or ECR-CVD; and then, a pattern including an active layer 1 is formed by a patterning process (film forming, exposing, developing, wet etching or dry etching).

Next, the substrate 9, on which the active layer 1 of the oxide thin film transistor is formed, is annealed. The annealing duration is preferably 30-60 min. When the annealing duration is too short, it is unable to effectively enable the diffusion of metal atoms in the source-drain metal thin film 20 towards the active layer, while when the annealing duration is too long, since the metal diffusion achieves a balance, it may prolong the production cycle and cause waste and thus increase the cost.

The annealing temperature is preferably 230-320° C. When the annealing temperature is within the above range, the performance of the active layer 1 may become more stable.

On the substrate 9 subjected to the above step, a pattern including a source 21 and a drain 22 of an oxide thin film transistor is formed by a patterning process.

In this step, a source-drain metal thin film 20 is deposited by PECVD, LPCVD, APCVD or ECR-CVD or sputtering; and then, a pattern including a source 21 and a drain 22 is formed by a patterning process (film forming, exposing, developing, wet etching or dry etching).

Hereafter, the substrate 9 subjected to the above step (the substrate 9 on which the source and the drain of the thin film transistor are formed) is annealed. At that time, the annealing temperature is preferably 30-320° C., and the annealing duration is preferably 5-10 min.

In this step, at positions where the source 21 and the drain 22 come into contact with the active layer 1, the diffusion of metal atoms in the metal material forming the source 21 and the drain 22 toward the active layer 1 can be facilitated, the metal atoms entering the active layer 1 by diffusion undergo chemical reaction with oxygen atoms in the oxide semiconductor material forming the active layer 1. As a result, the active layer 1 material at those positions undergoes oxygen loss. That is, the oxygen vacancies are increased, and the free electrons are increased accordingly. Consequently, the semiconductor material at those positions has a metalized (semiconductor) tendency. Hence, the Ohmic contact between the source 21 and the active layer 1 and between the drain 22 and the active layer 1, respectively, is further increased. In addition, the stability of the channel region of the active layer 1 may be enhanced. Herein, annealing in the presence of air or O₂ may supplement O₂ to the active layer 1. The content of oxygen in the active layer is controlled so that the characteristics of the semiconductor in the active layer become more stable, and thus the performance of the oxide thin film transistors becomes better.

The oxide semiconductor thin film 10 is made of any one of ITO (indium tin oxide), IZO (indium zinc oxide), IGZO (indium gallium zinc oxide) or InGaSnO (indium gallium tin oxide). The oxide semiconductor thin film 10 has a thickness of 40-50 nm, and during the deposition, the content of oxygen in the deposition atmosphere is 15%-30%. The source-drain metal thin film 20 is made of any one of molybdenum, molybdenum-niobium alloy, aluminum, aluminum-neodymium alloy, titanium or copper. The source-drain metal thin film 20 has a thickness of 20-30 nm.

It is to be noted that the source-drain metal thin film 20 may be a single-layer structure of metal, may also be a dual-layer structure of buffer metal/metal, and may also be a tri-layer structure of buffer metal/metal/buffer metal.

The subsequent other steps are the same as those in Embodiment 2, and will not be described in detail herein.

Correspondingly, in this embodiment, an oxide thin film transistor is further provided, which is manufactured according to the manufacturing method as described above, so the performance of this oxide thin film transistor is more stable.

It is to be noted herein that, in Embodiments 1-3, description is given by taking the manufacturing of a top-gate oxide thin film transistor as an example. It may be understood by those skilled in the art that the most significant difference between a top-gate thin film transistor and a bottom-gate thin film transistor lies in the positions of the active layer 1 and the gate 4, wherein if the active layer 1 is located above the gate 4, it is called a top-gate thin film transistor, and if the active layer 1 is located below the gate 4, it is called a bottom-gate thin film transistor. Hence, the method for manufacturing a bottom-gate oxide thin film transistor is also within the protection scope of this embodiment, and will not be described in detail herein.

### Embodiment 4

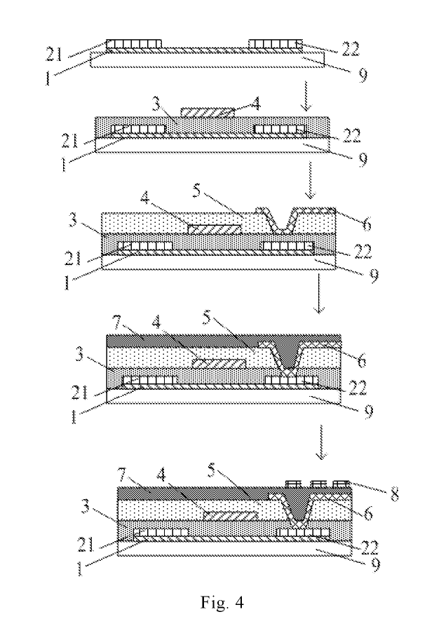

FIG. 4 is a schematic diagram of a method for manufacturing an array substrate of Embodiment 4 of the present invention. As shown in FIG. 4, this embodiment provides a method for manufacturing an array substrate, including the method for manufacturing an oxide thin film transistor according to any one of Embodiments 1-3. Specifically:

A passivation layer 5 is formed on the substrate 9 on which the structure of various layers of a thin film transistor are formed.

In this step, a passivation layer 5 is formed by thermal growth, atmospheric pressure chemical vapor deposition, LPCVD, plasma assisted chemical vapor deposition, sputtering or the like.

The passivation layer 5 may be made of silicon oxide (SiOx), silicon nitride (SiNx), hafnium oxide (HfOx), silicon oxynitride (SiON), aluminum oxide (AlOx) or the like, or may be made of a multi-layer film of two or three thereof. The passivation layer 5 has a thickness of 200-400 nm.

A pattern including a pixel electrode 6 is formed on the substrate 9 by a patterning process. The pixel electrode 6 is connected to the drain 22 through a via hole penetrating through the passivation layer 5 and the gate insulating layer 3.

In this step, a first transparent conductive thin film is formed by sputtering, thermal evaporation, PECVD, LPCVD, APCVD or ECR-CVD, and a pattern including a pixel electrode 6 is formed by photoresist applying, exposing, developing, etching, photoresist stripping on this first transparent conductive thin film.

The first transparent conductive thin film has a high reflectivity and meets certain work function requirements, and usually adopts a dual-layer film or tri-layer film structure, for example, an ITO (indium tin oxide)/Ag (silver)/ITO (indium tin oxide), or Ag (silver)/ITO (indium tin oxide) structure. Or else, ITO in the above structure is replaced with IZO (indium zinc oxide), IGZO (indium gallium zinc oxide) or InGaSnO (indium gallium tin oxide). Of course, it may also be made of an inorganic metal oxide, organic conductive polymer or metal material having a conductive property and a high work function value. The inorganic metal oxide includes ITO or ZnO; the organic conductive polymer includes PEDOT: SS, PANI; and the metal material includes gold, copper, silver or platinum. The first transparent conductive thin film has a thickness of 40-70 nm.

On the substrate 9 subjected to the above step, a pattern including a planarization layer 7 is formed.

In this step, a planarization layer 7 is formed by thermal growth, atmospheric pressure chemical vapor deposition, LPCVD, plasma assisted chemical vapor deposition, sputtering or other manufacturing method.

The planarization layer 7 may be made of silicon oxide (SiOx), silicon nitride (SiNx), hafnium oxide (HfOx), silicon oxynitride (SiON), aluminum oxide (AlOx) or the like, or may be made of a multi-layer film of two or three thereof. The planarization layer 7 has a thickness of 200-400 nm.

On the substrate 9 subjected to the above step, a pattern including a common electrode 8 is formed by a patterning process.

In this step, a second transparent conductive thin film is formed by sputtering, thermal evaporation, PECVD, LPCVD, APCVD or ECR-CVD, and a pattern including a pixel electrode 6 is formed by photoresist applying, exposing, developing, etching, photoresist stripping on this second transparent conductive thin film.

The second transparent conductive thin film is made of any one of ITO (indium tin oxide)/Ag (silver)/ITO (indium tin oxide) or Ag (silver)/ITO (indium tin oxide) structure. Or else, ITO in the above structure is replaced with any one of IZO (indium zinc oxide), IGZO (indium gallium zinc oxide) or InGaSnO (indium gallium tin oxide). The second transparent conductive thin film has a thickness of 40-70 nm.

So far, an array substrate has been manufactured.

Correspondingly, in this embodiment, an array substrate is further provided, which is manufactured according to the manufacturing method as described above, so the performance of this array substrate is more stable.

### Embodiment 5

This embodiment provides a display device including the array substrate as described above. This display device may be a liquid crystal panel, electronic paper, an OLED panel, a mobile phone, a tablet, a TV set, a display, a laptop, a digital photo frame, a navigator or any other product or component having a display function.

It may be understood that the above embodiments are merely exemplary implementations used for explaining the principle of the present invention, but the present invention is not limited thereto. For a person of ordinary skill in the art, various variations and improvements may be made without departing from the spirit and essence of the present invention, and those variations and improvements are also regarded as falling into the protection scope of the present invention.

1. A method for manufacturing an oxide thin film transistor, comprising:
a step of forming a pattern comprising an active layer, a source and a drain above a substrate by a patterning process; and
a step of annealing the substrate subjected to the above step.

2. The method for manufacturing an oxide thin film transistor according to claim 1, characterized in that the step of forming a pattern comprising an active layer, a source and a drain by a patterning process comprises:
successively depositing an oxide semiconductor thin film and a source-drain metal thin film, and forming a pattern comprising an active layer, a source and a drain by a single patterning process.

3. The method for manufacturing an oxide thin film transistor according to claim 2, characterized in that annealing of the substrate, above which the active layer, the source and the drain are formed, is performed for 30-60 min at a temperature of 230-320° C.

4. The method for manufacturing an oxide thin film transistor according to claim 1, characterized in that the step of forming a pattern comprising an active layer, a source and a drain by a patterning process comprises:
a step of depositing an oxide semiconductor thin film, and forming a pattern comprising an active layer by a patterning process; and
a step of depositing a source-drain metal thin film, and forming a pattern comprising a source and a drain by a patterning process.

5. The method for manufacturing an oxide thin film transistor according to claim 4, wherein before the step of forming a pattern comprising a source and a drain by a patterning process, the method further comprises:
a step of annealing the substrate above which the active layer is formed.

6. The method for manufacturing an oxide thin film transistor according to claim 5, characterized in that in the step of annealing the substrate above which the active layer is formed, the annealing is performed for 30-60 min at a temperature of 230-320° C.

7. The method for manufacturing an oxide thin film transistor according to claim 4, characterized in that in the step of annealing the substrate above which the source and the drain of the thin film transistor are formed, the annealing is performed for 5-10 min at a temperature of 230-320° C.

8. The method for manufacturing an oxide thin film transistor according to claim 5, characterized in that in the step of annealing the substrate above which the source and the drain of the thin film transistor are formed, the annealing is performed for 5-10 min at a temperature of 230-320° C.

9. The method for manufacturing an oxide thin film transistor according to claim 6, characterized in that in the step of annealing the substrate above which the source and the drain of the thin film transistor are formed, the annealing is performed for 5-10 min at a temperature of 230-320° C.

10. The method for manufacturing an oxide thin film transistor according to claim 1, characterized in that the source and the drain are made of any one of molybdenum, molybdenum-niobium alloy, aluminum, aluminum-neodymium alloy, titanium and copper.

11. An oxide thin film transistor, being manufactured by the method for manufacturing an oxide thin film transistor according to claim 1.

12. An oxide thin film transistor, being manufactured by the method for manufacturing an oxide thin film transistor according to claim 2.

13. An oxide thin film transistor, being manufactured by the method for manufacturing an oxide thin film transistor according to claim 3.

14. An oxide thin film transistor, being manufactured by the method for manufacturing an oxide thin film transistor according to claim 4.

15. An oxide thin film transistor, being manufactured by the method for manufacturing an oxide thin film transistor according to claim 5.

16. A method for manufacturing an array substrate, comprising the method for manufacturing an oxide thin film transistor according to claim 1.

17. The method for manufacturing an array substrate according to claim 16, further comprising:
after the step of annealing a substrate above which a source and a drain are formed, depositing a passivation layer and forming a via hole through which a pixel electrode is connected to the drain by etching; and
forming a pattern comprising a pixel electrode by a patterning process, the pixel electrode being connected to the drain through the via hole.

18. The method for manufacturing an array substrate according to claim 17, characterized in that the passivation layer is a single-layer structure of silicon dioxide, or a dual-layer structure of silicon dioxide and silicon nitride, or a tri-layer structure of silicon dioxide, silicon nitride and silicon oxynitride.

19. An array substrate, being manufactured by the method for manufacturing an array substrate according to claim 16.

20. A display device comprising the array substrate according to claim 19.
